(19) United States
(12) Patent Application Publication
(10) Pub. No.: US 2026/0190820 A1
(43) Pub. Date: Jul. 2, 2026

(54) DISPLAY PANEL, DRIVING METHOD THEREOF, AND DISPLAY DEVICE

(71) Applicant: BOE Technology Group Co., Ltd., Beijing (CN)

(72) Inventors: Hao ZHANG, Beijing (CN); Mingche HSIEH, Beijing (CN)

(21) Appl. No.: 18/861,519

(22) PCT Filed: Aug. 12, 2024
(86) PCT No.: PCT/CN2024/111497

§ 371 Date: Oct. 29, 2024

(30) Foreign Application Priority Data
Sep. 28, 2023 (CN) 202311282370.4

(51) Int. Cl. H10K 59/80

(52) U.S. Cl. CPC H10K 59/8792

(57) ABSTRACT

The present disclosure provides a display panel, a driving method thereof, and a display device. The display panel includes: a substrate, and a first light-emitting element and a second light-emitting element located on a side of the substrate. A side of the substrate close to the first light-emitting element and the second light-emitting element is further provided with a first groove for accommodating the first light-emitting element and a second groove for accommodating the second light-emitting element, the depth of the first groove along the first direction is greater than the depth of the second groove along the first direction, and the first direction is the direction from the substrate to the first light-emitting element and the second light-emitting element. In the present disclosure, when the organic light-emitting layer located in the first groove emits light, it may block the light emitted at a large angle through the restriction of the groove structure, thereby avoiding light leakage on the side of the organic light-emitting layer away from the substrate that leads to large-angle light emission and affects the display effect, which may improve the peep-proof effect of the display panel in the peep-proof mode.

### TECHNICAL FIELD

The present disclosure relates to the display technology, and in particular, to a display panel, a driving method thereof, and a display device.

### BACKGROUND

Display products such as a mobile phone have become an important part of people's daily lives. In some scenarios, people need to share their screens with others to achieve information exchange and transmission, i.e., the shared state; in other scenarios, when people browse important or confidential content on display products such as a mobile phone, they need display products such as a mobile phone to only transmit the information on the display screen to the holder, while no one else can peep, i.e., the peep-proof state. Therefore, flexible switching between the shared state and peep-proof state has gradually become a functional requirement for display products such as a mobile phone.

### SUMMARY

In view of the shortcomings of the related art, the present disclosure proposes a display panel, a driving method thereof, and a display device, to solve the problem of how to improve the peep-proof effect of the display panel in the peep-proof mode in the related art.

Embodiments of the present disclosure provide a display panel, including: a substrate, and a first light-emitting element and a second light-emitting element, where the first light-emitting element and the second light-emitting element are located on a side of the substrate; a side of the substrate close to the first light-emitting element and the second light-emitting element is provided with a first groove for accommodating the first light-emitting element and a second groove for accommodating the second light-emitting element, a depth of the first groove along a first direction is greater than a depth of the second groove along the first direction, and the first direction is a direction from the substrate to the first light-emitting element and the second light-emitting element.

For the display panel provided by the embodiments, in the embodiments, a side of the substrate towards the first light-emitting element and the second light-emitting element is respectively provided with a first groove for accommodating the first light-emitting element and a second groove for accommodating the second light-emitting element, where the depth of the first groove is greater than the depth of the second groove, which may achieve that, through the recessed first groove on the display panel, the viewing angle range of the display panel in the peep-proof mode is reduced, when the organic light-emitting layer located in the first groove emits light, it may block the light emitted at a large angle through the restriction of the groove structure, thereby avoiding light leakage on the side of the organic light-emitting layer away from the substrate that leads to large-angle light emission and affects the display effect, which may further enhance the peep-proof, improving the peep-proof effect of the display panel in the peep-proof mode.

In an embodiment, a first groove for accommodating the first light-emitting element and a second groove for accommodating the second light-emitting element are further arranged on the substrate, where a depth of the first groove along a first direction is greater than a depth of the second groove along the first direction, and the first direction is a direction from the substrate to the first light-emitting element and the second light-emitting element.

In an embodiment, a ratio of the depth of the first groove along the first direction to the depth of the second groove along the first direction is 2 to 8;

In an embodiment, the first groove has a recessed surface with an opening direction towards the first direction, where a maximum angle formed by a line connecting any two points in the recessed surface and a plane perpendicular to the first direction is not less than 30° and not greater than 60°.

In an embodiment, the display panel further includes an isolation structure, the isolation structure is at least partially located on a side of the first light-emitting element and the second light-emitting element away from the substrate. On a plane perpendicular to the first direction, the isolation structure is at least partially located between the first light-emitting element and the second light-emitting element, and an orthographic projection of the isolation structure on the substrate does not overlap with an orthographic projection of the first groove on the substrate.

In an embodiment, both the first light-emitting element and the second light-emitting element include a first electrode, an organic light-emitting layer, and a second electrode sequentially stacked on the substrate, and on a plane perpendicular to the first direction, interfacial regions are formed between the first light-emitting element and the second light-emitting element, the interfacial regions include a first interfacial region and a second interfacial region, where,
the isolation structure is arranged in the first interfacial region, and separates the first electrode, the organic light-emitting layer, and the second electrode of the first light-emitting element from the first electrode, the organic light-emitting layer, and the second electrode of the second light-emitting element, respectively; and
the isolation structure is not arranged in the first interfacial region, and for the first light-emitting element and the second light-emitting element, conduction between the second electrodes is achieved through the second interfacial region.

In an embodiment, a ratio of a height of the isolation structure along the first direction to the depth of the first groove along the first direction is 0.5 to 1.

In an embodiment, the isolation structure is an integrated structure, a projection area of the orthographic projection of the isolation structure on the substrate gradually increases along the first direction.

In an embodiment, the isolation structure includes a first isolation portion and a second isolation portion sequentially stacked on the substrate, an orthographic projection of an end face of the first isolation portion facing the second isolation portion on the substrate is located in an orthographic projection of the second isolation portion on the substrate, and, a projection area of the orthographic projection of the end face of the first isolation portion facing the second isolation portion on the substrate is smaller than a projection area of the orthographic projection of the second isolation portion on the substrate.

In an embodiment, the display panel further includes a light blocking structure, located on a side of the isolation structure away from the substrate, where an orthographic projection of the light blocking structure on the substrate at least partially overlaps with the orthographic projection of the isolation structure on the substrate, a light exit blind region is formed between the light blocking structure and the isolation structure, and the light exit blind region is located outside an angle range of a first viewing angle.

In an embodiment, a height of the isolation structure along the first direction is less than a height of the light blocking structure along the first direction.

in an embodiment, a width of the isolation structure in a direction perpendicular to the first direction is greater than a width of the light blocking structure in a direction perpendicular to the first direction.

In an embodiment, the display panel further includes a first light adjusting structure, an orthographic projection of the first light adjusting structure on the substrate at least partially overlaps with the angle range of the first viewing angle, the first light adjusting structure is located on a side of the first light-emitting element away from the substrate, the first light adjusting structure includes a first refraction layer and a second refraction layer sequentially stacked on the substrate, and a refractive index of the first refraction layer is less than a refractive index of the second refraction layer.

In an embodiment, the first light adjusting structure is at least partially located in the first groove.

In an embodiment, the first light adjusting structure is located between the isolation structure and the light blocking structure.

In an embodiment, the first light adjusting structure is located on a side of the light blocking structure away from the substrate.

In an embodiment, the display panel further includes a second light adjusting structure, the second light adjusting structure includes a lens structure layer, an orthographic projection of the second light adjusting structure on the substrate at least partially overlaps with an orthographic projection of the first light-emitting element on the substrate.

In an embodiment, the second light adjusting structure is at least partially located in the first groove.

In an embodiment, the second light adjusting structure is located between the isolation structure and the light blocking structure.

In an embodiment, the second light adjusting structure is located between the light blocking structure and the first light adjusting structure.

In an embodiment, the second light adjusting structure is located on a side of the first light adjusting structure away from the substrate.

In an embodiment, the isolation structure and/or the light blocking structure is a light absorbing material or a light reflecting material.

The present disclosure further provides a driving method of a display panel, for driving the display panel as described in the above embodiment, where the driving method includes:
in peep-proof mode, controlling the first light-emitting element to emit light; and
in shared mode, controlling the second light-emitting element to emit light.

In an embodiment, in the shared mode, the first light-emitting element is controlled to emit light while the second light-emitting element is controlled to emit light.

The present disclosure provides a display device including the display panel as described in the above embodiment.

The additional aspects and advantages of present disclosure will be partially provided in the following description, which will become apparent from the following description or can be understood through the practice of present disclosure.

### BRIEF DESCRIPTION OF DRAWINGS

The accompanying drawings, which are incorporated in and constitute a part of the present description, illustrate embodiments consistent with the present disclosure and serve to explain the principles of the present disclosure together with the description.

FIG. 1 is a film layer structure diagram of a display panel according to an embodiment of the present disclosure;

FIG. 2 is a layout diagram of a display panel according to an embodiment of the present disclosure;

FIG. 3 is a film layer structure diagram of another display panel according to an embodiment of the present disclosure;

FIG. 4 is a film layer structure diagram of another display panel according to an embodiment of the present disclosure;

FIG. 5 is a film layer structure diagram of another display panel according to an embodiment of the present disclosure;

FIG. 6 is a film layer structure diagram of another display panel according to an embodiment of the present disclosure;

FIG. 7 is a film layer structure diagram of another display panel according to an embodiment of the present disclosure;

FIG. 8 is a film layer structure diagram of another display panel according to an embodiment of the present disclosure.

In the drawings: 1—substrate; 2—planarization layer; 201—first groove; 202—second groove; 3—first electrode; 4—pixel definition layer; 5—isolation structure; 51—first isolation portion; 52—second isolation portion; 6—organic light-emitting layer; 7—second electrode; 100—first light-emitting element; 200—second light-emitting element; 8—light blocking structure; 9—first light adjusting structure; 91—first refraction layer; 92—second refraction layer; 10—second light adjusting structure; LA1—first light-emitting region; LA2—second light-emitting region; CA—interfacial region; CA1—first interfacial region; CA2—second interfacial region; DA—light exit blind region.

### DETAILED DESCRIPTION

Embodiments will be described in detail here, examples of which are illustrated in the accompanying drawings. When the following description relates to the accompanying drawings, unless specified otherwise, the same numerals in different drawings represent the same or similar elements. The implementations described in the following exemplary embodiments do not represent all implementations consistent with the present disclosure. Conversely, they are merely examples of apparatuses and methods consistent with some aspects of the present disclosure as detailed in the appended claims.

The terms used in this disclosure are merely for the purpose of describing specific embodiments, and are not intended to limit this disclosure. The terms “a”, “said” and “the” of singular forms used in this disclosure and the appended claims are also intended to include plural forms, unless the context clearly indicates otherwise. It should also be understood that, the term “and/or” used herein indicates and includes any or all possible combinations of one or more associated listed items.

It should be understood that when describing the structure of components, when a layer or a region is referred to as being “above” or “on” another layer or region, it may mean directly above the another layer or region, or it may also mean that there are other layers or regions between it and the another layer or region. In addition, if the component is flipped, that layer or region is to be “below” or “underneath” the another layer or region.

Display products such as a mobile phone have become an important part of people's daily lives. In some scenarios, people need to share their screens with others to achieve information exchange and transmission, i.e., the shared state; in other scenarios, when people browse important or confidential content on display products such as a mobile phone, they need display products such as mobile phones to only transmit the information on the display screen to the holder, while no one else can peep, i.e., the peep-proof state. Therefore, flexible switching between the shared state and peep-proof state has gradually become a functional requirement for display products such as a mobile phone.

The display panel, the driving method thereof, and the display device provided by the present application aim to solve the above technical problems in the related art.

The display panel, the driving method thereof, and the display device in embodiments of present disclosure are described in detail below with reference to the accompanying drawings. If there is no conflict, features in the embodiments described below may complement each other or be combined with each other.

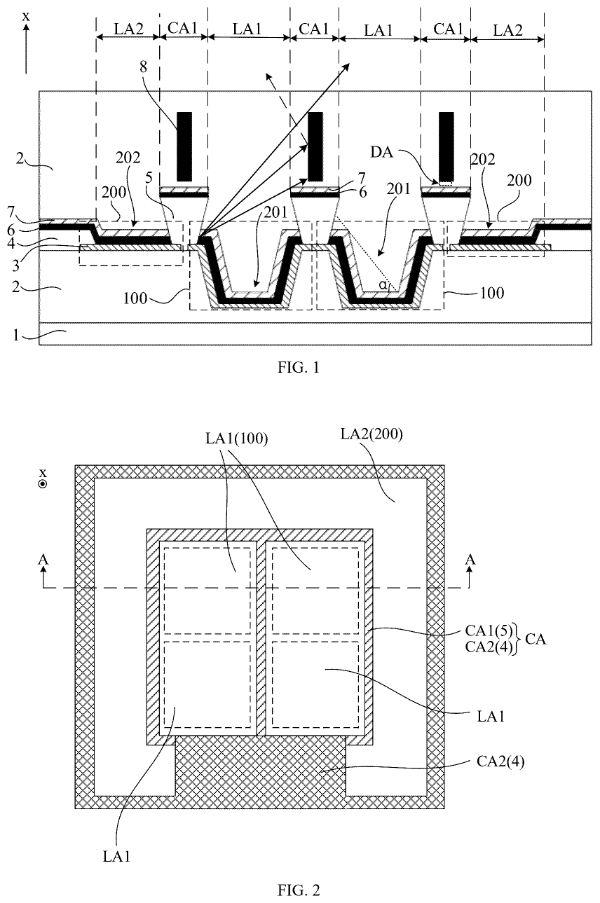

Embodiments of present disclosure provide a display panel, as illustrated in FIG. 1, including: a substrate 1; a first light-emitting element 100 and a second light-emitting element 200, located on a side of the substrate 1. A side of the substrate 1 close to the first light-emitting element 100 and the second light-emitting element 200 is provided with a first groove 201 for accommodating the first light-emitting element 100 and a second groove 202 for accommodating the second light-emitting element 200, where the depth of the first groove 201 along the first direction x is greater than the depth of the second groove 202 along the first direction x, and the first direction x is a direction from the substrate 1 to the first light-emitting element 100 and the second light-emitting element 200.

In the embodiments, the side of the substrate 1 towards the first light-emitting element 100 and the second light-emitting element 200 is provided with the first groove 201 for accommodating the first light-emitting element 100 and the second groove 202 for accommodating the second light-emitting element 200, requiring the depth of the first groove 201 to be greater than the depth of the second groove 202, which may achieve that, through the recessed first groove 201 on the display panel, the viewing angle range of the display panel in the peep-proof mode is reduced, when the organic light-emitting layer 6 located in the first groove 201 emits light, it may block the light emitted at a large angle through the restriction of the groove structure, thereby avoiding light leakage on the side of the organic light-emitting layer 6 away from the substrate 1 that leads to large-angle light emission and affects the display effect, which may further enhance the peep-proof, improving the peep-proof effect of the display panel in the peep-proof mode.

In some embodiments, the display mode of the display panel includes a peep-proof mode and a shared mode. In the peep-proof mode, the first light-emitting element 100 emits light, and the light exit viewing angle of the first light-emitting element 100 is the first viewing angle. In the shared mode, the second light-emitting element 200 emits light, and the light exit viewing angle of the second light-emitting element 200 is the second viewing angle. The angle range of the first viewing angle is smaller than the angle range of the second viewing angle.

For the display panel provided in the embodiments, in the peep-proof mode, the first light-emitting element 100 emits light to form the first viewing angle, i.e., the frontal viewing angle, enabling the display panel to emit light only to the holder facing it, with a narrower visible range, which may protect user privacy. In the shared mode, the second light-emitting element 200 emits light to form the second viewing angle, i.e., a larger wide viewing angle, enabling the display panel to have a larger visible angle range, enabling a plurality of people to share display information at the same time. The display panel in the embodiments may flexibly switch between the peep-proof mode and the shared mode, meeting the diverse display needs of daily life and office, which may enhance the user experience.

Considering that display products such as mobile phones are private items in life, whether in shared mode or peep-proof mode, the need to display at a viewing angle facing the holder is more frequent. Therefore, in some embodiments, as illustrated in FIG. 1, the projection area of the orthographic projection of the first light-emitting element 100 on the substrate 1 is greater than the projection area of the orthographic projection of the second light-emitting element 200 on the substrate 1. That is, the light-emitting area of the first light-emitting element 100 is greater than the light-emitting area of the second light-emitting element 200, which can increase the first viewing angle, that is, the light exit brightness within the light exit range of the first viewing angle can be increased, thereby optimizing the display effect of the display panel at the first viewing angle.

In some embodiments, as illustrated in FIG. 1, at least a part of the structure of the first light-emitting element 100 is closer to the substrate 1 than the second light-emitting element 200, i.e., at least a part of the structure of the first light-emitting element 100 is further away from the holder than the second light-emitting element 200. This enables, in the peep-proof mode, the light exit path of the first light-emitting element 100 to be longer, forming a relatively smaller first viewing angle, which is conducive to peep-proof.

In some embodiments, the light exit color of the first light-emitting element 100 and that of the second light-emitting element 200 are the same, and when a RGB pixel light-emitting manner is adopted, the color of the first light-emitting element 100 and second light-emitting element 200 is any one of red, green, or blue. When a WRGB pixel light-emitting manner is adopted, the color of the first light-emitting element 100 and second light-emitting element 200 is any one of red, green, blue, or white.

In some embodiments, the first viewing angle may be set according to the user's usage viewing angle frequency needs. This embodiment only provides an example where the first viewing angle is the frontal viewing angle. Technicians in the art may set the first viewing angle flexibly, which may be a side viewing angle, a top viewing angle, or a top viewing angle, but is not limited thereto.

In some embodiments, in the shared mode, the first light-emitting element 100 may also emit light to avoid the problem of uneven brightness due to a significant difference in brightness of light-emitting regions of the first light-emitting element 100 and the second light-emitting element 200 caused by that the first light-emitting element 100 does not emit light and the second light-emitting element 200 emit light, so as to further optimize the display effect.

In some embodiments, as illustrated in FIG. 1, both the first light-emitting element 100 and the second light-emitting element 200 include a first electrode 3, an organic light-emitting layer 6, and a second electrode 7. One side of the first electrode 3 is connected to the pixel driving circuit (not illustrated in the figure) corresponding to the light-emitting element, the other side of the first electrode 3 is connected to a side of the organic light-emitting layer 6, and a side of the organic light-emitting layer 6 away from the first electrode 3 is connected to the second electrode 7. The organic light-emitting layer 6 emits light by utilizing the light-emitting characteristics of organic materials under the drive of the pixel driving circuit. In the embodiment, the first electrode 3 is an anode, and the second electrode 7 is a cathode. In some other embodiments, the first electrode 3 is a cathode, and the second electrode 7 is an anode.

In some embodiments, the organic light-emitting layer 6 may include an emitting layer (EML), and any one or more of the following: one or more layers of a hole injection layer (HIL), a hole transport layer (HTL), a hole blocking layer (HBL), an electron blocking layer (EBL), an electron injection layer (EIL), and an electron transport layer (ETL).

In some embodiments, the substrate 1 may be a rigid substrate or a flexible substrate, the material of the rigid substrate may be glass or quartz, and the flexible substrate may be polymer materials, such as polyimide (PI), polycarbonate (PC), polyethylene terephthalate (PET), polyethylene naphthalate (PEN) or graphite. The substrate 1 may be a single layer structure, or may be a stacked layer structure composed of an inorganic material layer and an organic material layer, which is not limited in the present disclosure.

In some embodiments, the first light-emitting element 100 and the second light-emitting element 200 are any one or more of an organic light-emitting diode (OLED), an active matrix organic light-emitting diode (AMOLED), a passive matrix organic light-emitting diode (PMOLED), a quantum dot organic light-emitting diode (QLED), a micro light-emitting diode (Micro-LED), and a mini light-emitting diode (Mini-LED).

In some embodiments, since the depth of the first groove 201 is greater than the depth of the second groove 202, compared with the traditional method of using a pixel definition layer 4 to define the light-emitting region of the light-emitting unit and the light-emitting unit along the first direction x, the embodiments may flexibly set the light-emitting area of the first light-emitting element 100 and the depths of the first electrode 3, the organic light-emitting layer 6, and the second electrode 7, so that the light-emitting area of the first light-emitting element 100 is greater than the light-emitting area of the second light-emitting element 200, and the depth of the light-emitting material of the first light-emitting element 100 is greater than the depth of the light-emitting material of the second light-emitting element 200, so as to enhance the brightness of the light exiting from the front and optimize the display effect.

In some embodiments, as illustrated in FIG. 1, the display panel further includes planarization layers 2 located on the substrate 1 and close to the first light-emitting element 100 and the second light-emitting element 200, and the first groove 201 is formed in a planarization layer 2.

In some embodiments, as illustrated in FIG. 1, the display panel further includes a pixel definition layer 4 located on the planarization layer 2 and close to the first light-emitting element 100 and the second light-emitting element 200. The pixel definition layer 4 has a plurality of pixel definition units arranged at intervals, and a second groove 202 is formed between adjacent pixel definition units.

In some embodiments, the material of the pixel definition layer 4 includes an inorganic insulating material or an organic insulating material. For example, the inorganic insulating materials may be silicon nitride, silicon oxide or silicon oxynitride. Organic insulating materials may be polyimide (PI), benzocyclobutene (BCB), and a photoresist material.

In some embodiments, the ratio of the depth of the first groove 201 along the first direction x to the depth of the second groove 202 along the first direction x is 2 to 8. In the embodiment, the depth of the second groove 202 is less than the depth of the first groove 201, enabling the viewing angle range of the second viewing angle formed by the light emitted by the second light-emitting element 200 in the second groove 202 to be larger than that of the first viewing angle formed by the light emitted by the first light-emitting element 100 in the first groove 201, which may achieve that, in the shared mode, the second light-emitting element 200 emits light with a large viewing angle, achieving better switching display effects of the display panel between the shared mode and the peep-proof mode.

In some embodiments, the ratio of the depth of the first groove 201 along the first direction x to the depth of the second groove 202 along the first direction x is 4. For example, the depth of the first groove 201 along the first direction x is 4 μm, and the depth of the second groove 202 along the first direction x is 1 μm.

In some embodiments, as illustrated in FIG. 1, the first groove 201 has a recessed surface with an opening direction towards the first direction x, where a maximum angle a formed by a line connecting any two points in the recessed surface and a plane perpendicular to the first direction x is not less than 30° and not greater than 60°.

In the embodiments, the maximum angle a between the light exiting out from the first groove 201 and the plane where the substrate 1 is located is not less than 30° and not greater than 60°, where the maximum angle α is an angle value or angle range preset according to test data and actual needs. In the embodiment, the angle of the light exiting out from the first groove 201 is limited, which may more comprehensively block all light with a large viewing angle, achieving comprehensive peep-proof. In an example, the maximum angle α is 45°, which may achieve a peep-proof effect where the display screen may only be observed within a limited 45° angle.

In some embodiments, as illustrated in FIG. 1, the orthographic projection of the opening of the first groove 201 on the substrate 1 gradually increases along the first direction x, so as to achieve that the light emitted by the organic light-emitting layer 6 of the light-emitting element is emitted at a predetermined angle after being refracted on a sidewall, which avoids the light being completely blocked or absorbed, so as to enhance the display brightness of the display panel. For example, as illustrated in FIG. 1, the shape of the first groove 201 is an inverted trapezoid, and the projection area of the orthographic projection of the end face of the first groove 201 close to the substrate 1 on the substrate 1 is smaller than the projection area of the opening of the first groove 201 away from the substrate 1 on the substrate 1.

In some embodiments, as illustrated in FIG. 1, the display panel further includes an isolation structure 5. The isolation structure 5 is at least partially located on a side of the first light-emitting element 100 and the second light-emitting element 200 away from the substrate 1. On a plane perpendicular to the first direction x, the isolation structure 5 is at least partially located between the first light-emitting element 100 and the second light-emitting element 200, and the orthographic projection of the isolation structure 5 on the substrate 1 does not overlap with the orthographic projection of the first groove 201 on the substrate 1.

In the embodiments, the isolation structure 5 is provided in the display panel, there is no overlap between the orthographic projections of the isolation structure 5 and the first groove 201 on the substrate 1, so as to achieve as much light emission as possible, avoiding the blockage and absorption of light caused by the overlap at the bottom of the isolation structure 5, and thereby adjusting the light exit angle of the first light-emitting element 100 with the isolation structure 5 located around the first groove 201 and thus increasing the brightness of the first light-emitting element 100. In addition, the isolation structure 5 is set between the first light-emitting element 100 and the second light-emitting element 200, which may separate the first electrodes 3, the organic light-emitting layers 6, and the second electrodes 7 between the first light-emitting elements 100 and the second light-emitting elements 200. For example, the bottom of the isolation structure 5 is in direct contact with the upper surface of the planarization layer 2, and is at least partially in direct contact with the first electrodes 3 of the first light-emitting element 100 and the second light-emitting element 200. Separating the first electrodes 3 and the second electrodes 7 of the two light-emitting elements may avoid signal interference between the first light-emitting element 100 and the second light-emitting element 200, which is convenient to control the first light-emitting element 100 and the second light-emitting element 200 separately. Separating the organic light-emitting layers 6 of the two light-emitting elements may avoid color crosstalk caused by the crosstalk between the light-emitting materials of the organic light-emitting layers 6.

In some embodiments, the material of the isolation structure 5 is polyimide (PI), benzocyclobutene (BCB), or a photo spacer (PS) material.

In some embodiments, as illustrated in FIG. 1, the isolation structure 5 is also set between adjacent first light-emitting elements 100, and configured to separate the second electrodes 7 and organic light-emitting layers 6 between adjacent first light-emitting elements 100, so as to avoid signal interference between each first light-emitting element 100 or color crosstalk caused by crosstalk between the light-emitting materials of the organic light-emitting layers 6. In addition, each first light-emitting element 100 shares the same first electrode 3, facilitating simultaneous control of the first light-emitting elements 100, i.e., the isolation structure 5 is not in contact with the planarization layer 2. Using the isolation structure 5 in the embodiment to replace the pixel definition layer 4 in the traditional structure to separate adjacent first light-emitting elements 100, or the first light-emitting element 100 and the second light-emitting element 200 may, reduce the spacing between adjacent first light-emitting elements 100 or between the first light-emitting element 100 and the second light-emitting element 200, i.e., the positions of the light emitting elements are closer, so the light-emitting area of the first light emitting elements 100 and the second light emitting elements 200 may be correspondingly increased, thereby increasing the aperture ratio of the display panel.

It should be noted that, between adjacent second light-emitting elements 200, the isolation structure 5 may not be arranged, so as to achieve that the light emitted by the second light-emitting elements 200 emits at the maximum viewing angle, avoiding the blockage of the isolation structure 5. Each second light-emitting element 200 may share the same first electrode 3, to facilitate simultaneous control of the on and off of the second light-emitting elements 200, so as to enable the display products such as mobile phones to switch freely between the peep-proof mode and the shared mode.

In some embodiments, as illustrated in FIG. 1˜FIG. 2, FIG. 1 is a cross-sectional view corresponding to the cross-sectional line along the dashed line AA in FIG. 2. The first light-emitting element 100 is located in the first light-emitting region LA1, and the second light-emitting element 200 is located in the second light-emitting region LA2, the second light-emitting region LA2 at least partially surrounds the first light-emitting region LA1. Both the first light-emitting element 100 and the second light-emitting element 200 include a first electrode 3, an organic light-emitting layer 6, and a second electrode 7 stacked in sequence on the substrate 1. On a plane perpendicular to the first direction x, interfacial regions CA are formed between the first light-emitting element 100 and the second light-emitting element 200, the interfacial regions CA include a first interfacial region CA1 and a second interfacial region CA2. The first interfacial region CA1 has an isolation structure 5, and the isolation structure 5 separates the first electrode 3, organic light-emitting layer 6, and second electrode 7 of the first light-emitting element 100 from those of the second light-emitting element 200, respectively. The second interfacial region CA2 does not have an isolation structure 5, and the first light-emitting element 100 and the second light-emitting element 200 achieve conduction between the second electrodes 7 through the second interfacial region CA2.

In some embodiments, at least a part of the second electrodes 7 of the first light-emitting elements 100 and the second light-emitting elements 200 is anodes, the anodes between the first light-emitting elements 100 and the second light-emitting elements 200 are connected, which may achieve that the anode voltage is smoothly loaded onto the second electrodes 7 of the first light-emitting elements 100 or the second light-emitting elements 200, achieving smooth signal transmission, so as to achieve smooth switching between the peep-proof mode and the shared mode.

In some embodiments, as illustrated in FIG. 1, the ratio of the height of the isolation structure 5 along the first direction x to the depth of the first groove 201 along the first direction x is 0.5 to 1.

In the embodiments, the height of the isolation structure 5 in the first direction x is less than the depth of the first groove 201 in the first direction x. Since the first groove 201 has an adjusting role on the light emitted from the first light-emitting element 100, a relatively small-height isolation structure 5 may be set for a second adjustment of the emitted light after being adjusted or filtered by the first groove 201. In addition, when the height of the isolation structure 5 is relatively small, the structural stability of the isolation structure 5 is relatively high, and the display panel may also be thinned to enhance aesthetics and user experience. For example, the depth of the isolation structure 5 along the first direction x is 2˜3 μm, and the depth of the first groove 201 along the first direction x is 4˜6 μm.

In some embodiments, as illustrated in FIG. 1, the isolation structure 5 is an integrated structure, and the projection area of the orthographic projection of the isolation structure 5 on the substrate 1 gradually increases along the first direction x. For example, the isolation structure 5 is an inverted trapezoidal structure. It may achieve the isolation of the organic light-emitting layers 6 between adjacent first light-emitting elements 100 and between the first light-emitting element 100 and the second light-emitting element 200, avoiding crosstalk between pixels.

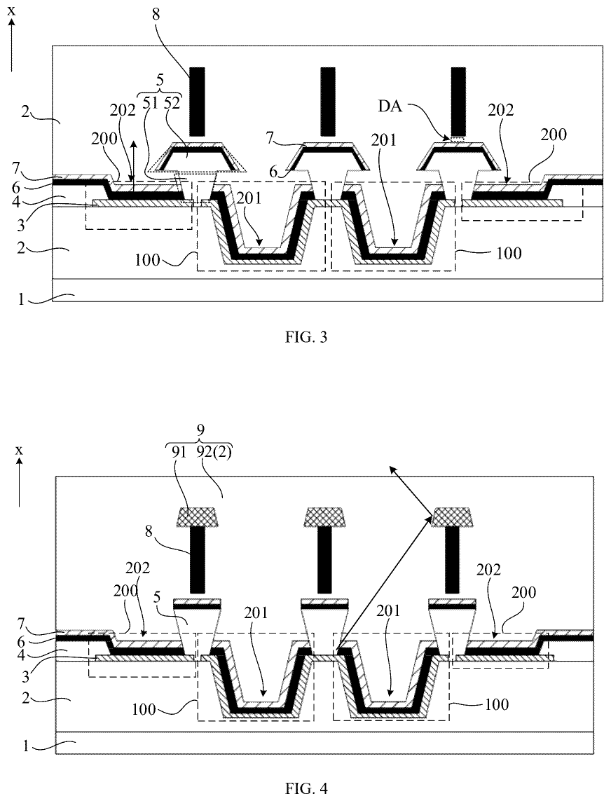

In some embodiments, as illustrated in FIG. 3, the isolation structure 5 includes a first isolation portion 51 and a second isolation portion 52 stacked in sequence on the substrate 1. The orthographic projection of the end face of the first isolation portion 51 facing the second isolation portion 52 on the substrate 1 is located in the orthographic projection of the second isolation portion 52 on the substrate 1, and, the projection area of the orthographic projection of the end face of the first isolation portion 51 facing the second isolation portion 52 on the substrate 1 is smaller than the projection area of the orthographic projection of the second isolation portion 52 on the substrate 1. For example, the isolation structure 5 is a T-shaped structure. Similarly to the aforementioned embodiments, since the width of the first isolation portion 51 is smaller than the width of the second isolation portion 52, it may achieve the isolation of the organic light-emitting layers 6 between adjacent first light-emitting elements 100 and between the first light-emitting element 100 and the second light-emitting element 200, avoiding crosstalk between pixels.

In some embodiments, as illustrated in FIG. 1 or FIG. 3, the height of the isolation structure 5 is greater than the height of the pixel definition layer 4.

In some embodiments, as illustrated in FIG. 3, the orthographic projection of the second isolation portion 52 of the isolation structure 5 on the substrate 1 overlaps both with the adjacent first light-emitting element 100 and the orthographic projection of the adjacent first light-emitting element 100 on the substrate 1.

In some embodiments, as illustrated in FIG. 1 or 3, the surface of the isolation structure 5 is further covered with an organic light-emitting layer 6 and a second electrode 7 that are disconnected from the first light-emitting element 100. For example, the upper surface and both side surfaces of the second isolation portion 52 of the isolation structure 5 are further covered with an organic light-emitting layer 6 and a second electrode 7 that are disconnected from the first light-emitting element 100.

In some embodiments, as illustrated in FIG. 1 or FIG. 3, the display panel further includes a light blocking structure 8, which is located on a side of the isolation structure 5 away from the substrate 1. The orthographic projection of the light blocking structure 8 on the substrate 1 at least partially overlaps with the orthographic projection of the isolation structure 5 on the substrate 1, and a light exit blind region DA is formed between the light blocking structure 8 and the isolation structure 5, and the light exit blind region DA is located outside the angle range of the first viewing angle.

In the embodiments, a light blocking structure 8 is arranged on a side of the isolation structure 5 away from the substrate 1. The light exit blind region DA between the light blocking structure 8 and the isolation structure 5 may be used to fill other functional film layers or be filled with a planarization material, which may eliminate the need to provide the light blocking structure 8 in the light exit blind area DA, saving material costs.

In some embodiments, as illustrated in FIG. 1 or FIG. 3, the height of the isolation structure 5 along the first direction x is less than the height of the light blocking structure 8 along the first direction x. In the embodiments, the height of the light blocking structure 8 is relatively high, which may compensate for the adjusting role for light that may be refracted through the isolation structure 5, further enhancing the peep-proof effect in the peep-proof mode.

In some embodiments, as illustrated in FIG. 1 or FIG. 3, the width of the isolation structure 5 in a direction perpendicular to the first direction x is greater than the width of the light blocking structure 8 in a direction perpendicular to the first direction x. In the embodiments, the width of the isolation structure 5 is greater than the width of the light blocking structure 8, which may adjust or absorb the light that may diffuse at the initial stage of light emission, to enhance the peep-proof effect.

In some embodiments, as illustrated in FIG. 4, the display panel further includes a first light adjusting structure 9, the orthographic projection of the first light adjusting structure 9 on the substrate 1 at least partially overlaps with the angle range of the first viewing angle, the first light adjusting structure 9 is located on a side of the first light-emitting element 100 away from the substrate 1, the first light adjusting structure 9 includes a first refraction layer 91 and a second refraction layer 92 sequentially stacked on the substrate 1, and the refractive index of the first refraction layer 91 is less than the refractive index of the second refraction layer 92. This may achieve that, through the refraction effect at the interface between the first refraction layer 91 and the second refraction layer 92, further reducing the angle range of the first viewing angle of the light emitted by the first light-emitting element 100, and enhancing the peep-proof effect of the display panel in the peep-proof mode.

In some embodiments, the refractive index of the first refraction layer 91 is 1.4˜1.6, and the refractive index of the second refraction layer 92 is 1.7˜1.9.

It should be noted that, the first light adjusting structure 9 may be a diffusion structure, which includes an internal extraction structure (IES) or an external extraction structure (EES).

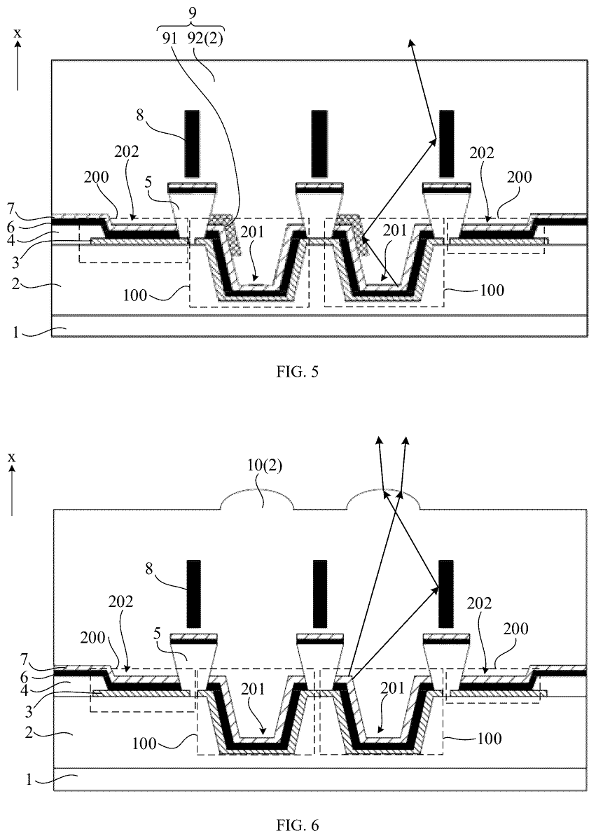

Specifically, in some embodiments, as illustrated in FIG. 5, the first light adjusting structure 9 is at least partially located in the first groove 201 and is in direct contact with the organic light-emitting layer 6 of the first light-emitting element 100, achieving the convergence of the emitted light by the first light adjusting structure 9. In some other embodiments (not illustrated in the figure), the first light adjusting structure 9 is located between the isolation structure 5 and the light blocking structure 8, and converges the light adjusted by the isolation structure 5. In some embodiments, as illustrated in FIG. 4, the first light adjusting structure 9 is located on a side of the light blocking structure 8 away from the substrate 1, and converges the light that has been adjusted by the light blocking structure 8. The above embodiments may be combined arbitrarily without conflict, so as to further narrow the viewing angle and enhance the peep-proof effect.

In some embodiments, as illustrated in FIG. 6, the display panel further includes a second light adjusting structure 10, which includes a lens structure layer, and the orthographic projection of the second light adjusting structure 10 on the substrate 1 at least partially overlaps with the orthographic projection of the first light-emitting element 100 on the substrate 1. This is to further reduce the angle range of the first viewing angle of the light emitted by the first light-emitting element 100 and enhance the peep-proof effect of the display panel in the peep-proof mode.

In some embodiments, as illustrated in FIG. 6, the lens structure layer includes a micro lens array (MLA) arranged on a plane perpendicular to the first direction x, the MLA includes a plurality of convex lenses. In some embodiments, the convex lens is a spherical lens, an aspherical lens, a cylindrical lens or a prism.

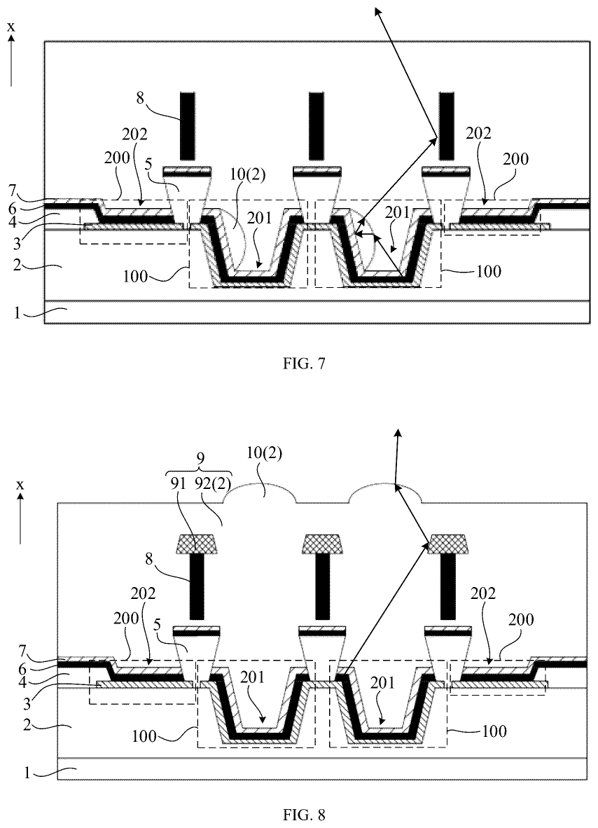

Specifically, similar to the first light adjusting structure 9, in some embodiments, as illustrated in FIG. 7, the second light adjusting structure 10 is at least partially located in the first groove 201. In some other embodiments (not illustrated in the figure), the second light adjusting structure 10 is located between the isolation structure 5 and the light blocking structure 8. In some other embodiments (not illustrated in the figure), the second light adjusting structure 10 is located between the light blocking structure 8 and the first light adjusting structure 9. In some other embodiments, as illustrated in FIG. 6 or FIG. 8, the second light adjusting structure 10 is located on a side of the first light adjusting structure 9 away from the substrate 1.

In some embodiments, the isolation structure 5 and/or the light blocking structure 8 is a light absorbing material or a light reflecting material. By absorbing and/or reflecting, it is possible to block the emission of light at a large viewing angle, so as to further enhance the peep-proof effect.

In some embodiments, the light-absorbing material includes at least one of acrylic materials and polyimide materials. The acrylate material include at least one of methyl acrylate, ethyl acrylate, n-butyl acrylate, isobutyl acrylate, n-propyl acrylate, 2-ethylhexyl acrylate, n-octyl acrylate, isooctyl acrylate, decyl acrylate, 2-hydroxyethyl acrylate, and 2-hydroxypropyl acrylate; and the polyimide material include at least one of aliphatic polyimide, aromatic polyimide, and polyetherimide. These materials may efficiently absorb emitted light at large viewing angles, and block light at large viewing angles by the absorption, and those are also low in price, which is beneficial for actual manufacturing processes and industrial production. In actual processes, the specific materials of the light-absorbing materials are selected according to actual needs.

In some embodiments, the material of the light blocking structure 8 may be metallic materials, e.g., silver, aluminum, or platinum, or insulating materials. It should be noted that, the material of the isolation structure 5 is an insulating material, so as to avoid signal crosstalk between the light-emitting elements on both sides of the isolation structure 5.

The embodiments further provide a driving method of a display panel, for driving the display panel as described in the above embodiment.

The driving method specifically includes: in the peep-proof mode, controlling the first light-emitting element 100 to emit light; and in the shared mode, controlling the second light-emitting element 200 to emit light.

In some embodiments, in the shared mode, while the second light-emitting element 200 is controlled to emit light, the first light-emitting element 100 is controlled to emit light. This may avoid uneven brightness of the display panel.

The present disclosure further provides a display device, including the display panel as described in the above embodiments. The display device has the advantages of the display panel in the above embodiments, which is therefore not repeated here.

It should be noted that, the display device may be any device that displays content, whether in motion (e.g., video) or stationary (e.g., still images), and whether textual or graphical. More specifically, the expected embodiments may be implemented in or associated with a variety of electronic devices, such as (but not limited to) mobile phones, wireless devices, personal digital assistants (PDAs), handheld or portable computers, GPS receivers/navigators, cameras, MP4 video players, camcorders, game consoles, watches, clocks, calculators, television monitors, flat panel displays, computer monitors, automotive displays (e.g., speedometer displays, etc.), navigators, cockpit controllers and/or displays, camera view displays (e.g., displays for rearview cameras in vehicles), electronic photos, electronic billboards or signs, projectors, building structures, packaging, and aesthetic structures (e.g., displays for images of a piece of jewelry), etc.

The above embodiments of the present disclosure, in the absence of conflicts, may complement each other.

It is to be noted that in the accompanying drawings, the dimensions of layers and regions may be exaggerated for clarity of illustration. It will be understood that when an element or a layer is referred to as being “above” or “on” another element or layer, it may be directly on the other element, or intervening layers may be present. In addition, it will be understood that when an element or a layer is referred to as being “under” or “below” another element or layer, it may be directly under the other element, or one or more intervening layers or elements may be present. In addition, it will also be understood that when a layer or an element is referred to as being “between” two layers or two elements, it may be the only layer between the two layers or two elements, or one or more intervening layers or elements may be present. Like reference numerals indicate like elements throughout.

The terms “center”, “up”, “bottom”, “front”, “back”, “left”, “right”, “vertical”, “horizontal”, “top”, “bottom”, “inside”, “outside”, etc., indicate orientations or positional relationships based on the orientations or positional relationships shown in the drawings and are intended solely for convenience and simplification of the present application, and do not indicate or imply that the device or element referred to must have a particular orientation, be constructed and operated in a particular orientation, and therefore cannot be construed as limiting the present application.

In addition, the terms “first” and “second” are only used for description, and cannot be construed as indicating or implying relative importance or implicitly indicating the number of indicated technical features. Thus, elements limited by “first” and “second” may explicitly or implicitly include one or more features. In the descriptions of the present disclosure, “a plurality” refers to two or more unless otherwise stated clearly.

Those skilled in the art will readily conceive other embodiments of the present disclosure upon consideration of the specification and practice of the various embodiments disclosed herein. This application is intended to cover any variation, use, or adaptive change of this application. These variations, uses, or adaptive changes follow the general principles of this application and include common general knowledge or common technical means in the art that are not disclosed in this application. The specification and the embodiments are considered as merely exemplary, and the real scope and spirit of the present disclosure are pointed out in the following claims.

It should be understood that this application is not limited to the precise structures described above and shown in the accompanying drawings, and various modifications and changes can be made without departing from the scope of this application. The scope of the present disclosure is limited only by the appended claims.

1. A display panel, comprising:
a substrate; and
a first light-emitting element and a second light-emitting element, located on a side of the substrate;
wherein a side of the substrate close to the first light-emitting element and the second light-emitting element is provided with a first groove for accommodating the first light-emitting element and a second groove for accommodating the second light-emitting element, a depth of the first groove along a first direction is greater than a depth of the second groove along the first direction, and the first direction is a direction from the substrate to the first light-emitting element and the second light-emitting element.

2. The display panel according to claim 1, wherein a ratio of the depth of the first groove along the first direction to the depth of the second groove along the first direction is 2 to 8;
and/or, the first groove has a recessed surface with an opening direction towards the first direction, wherein a maximum angle formed by a line connecting any two points in the recessed surface and a plane perpendicular to the first direction is not less than 30° and not greater than 60°.

3. The display panel according to claim 1, wherein the display panel further comprises an isolation structure, the isolation structure is at least partially located on a side of the first light-emitting element and the second light-emitting element away from the substrate; and
on a plane perpendicular to the first direction, the isolation structure is at least partially located between the first light-emitting element and the second light-emitting element, and an orthographic projection of the isolation structure on the substrate does not overlap with an orthographic projection of the first groove on the substrate.

4. The display panel according to claim 3, wherein both the first light-emitting element and the second light-emitting element comprise a first electrode, an organic light-emitting layer, and a second electrode sequentially stacked on the substrate, and on the plane perpendicular to the first direction, interfacial regions are formed between the first light-emitting element and the second light-emitting element, the interfacial regions comprise a first interfacial region and a second interfacial region, wherein, the isolation structure is arranged in the first interfacial region, and separates the first electrode, the organic light-emitting layer, and the second electrode of the first light-emitting element from the first electrode, the organic light-emitting layer, and the second electrode of the second light-emitting element, respectively; and
the isolation structure is not arranged in the first interfacial region, and for the first light-emitting element and the second light-emitting element, conduction between the second electrodes is achieved through the second interfacial region.

5. The display panel according to claim 3, wherein a ratio of a height of the isolation structure along the first direction to the depth of the first groove along the first direction is 0.5 to 1.

6. The display panel according to claim 3, wherein,
the isolation structure is an integrated structure, a projection area of the orthographic projection of the isolation structure on the substrate gradually increases along the first direction;
or, the isolation structure comprises a first isolation portion and a second isolation portion sequentially stacked on the substrate, an orthographic projection of an end face of the first isolation portion facing the second isolation portion on the substrate is located in an orthographic projection of the second isolation portion on the substrate, and a projection area of the orthographic projection of the end face of the first isolation portion facing the second isolation portion on the substrate is smaller than a projection area of the orthographic projection of the second isolation portion on the substrate.

7. The display panel according to claim 3, wherein the display panel further comprises a light blocking structure, located on a side of the isolation structure away from the substrate, wherein an orthographic projection of the light blocking structure on the substrate at least partially overlaps with the orthographic projection of the isolation structure on the substrate, a light exit blind region is formed between the light blocking structure and the isolation structure, and the light exit blind region is located outside an angle range of a first viewing angle.

8. The display panel according to claim 7, wherein a height of the isolation structure along the first direction is less than a height of the light blocking structure along the first direction;
and/or, a width of the isolation structure in a direction perpendicular to the first direction is greater than a width of the light blocking structure in the direction perpendicular to the first direction.

9. The display panel according to claim 7, wherein the display panel further comprises a first light adjusting structure, an orthographic projection of the first light adjusting structure on the substrate at least partially overlaps with the angle range of the first viewing angle, the first light adjusting structure is located on a side of the first light-emitting element away from the substrate, the first light adjusting structure comprises a first refraction layer and a second refraction layer sequentially stacked on the substrate, and a refractive index of the first refraction layer is less than a refractive index of the second refraction layer; wherein,
the first light adjusting structure is at least partially located in the first groove;
and/or, the first light adjusting structure is located between the isolation structure and the light blocking structure;
and/or, the first light adjusting structure is located on a side of the light blocking structure away from the substrate.

10. The display panel according to claim 9, wherein the display panel further comprises a second light adjusting structure, the second light adjusting structure comprises a lens structure layer, an orthographic projection of the second light adjusting structure on the substrate at least partially overlaps with an orthographic projection of the first light-emitting element on the substrate, wherein,
the second light adjusting structure is at least partially located in the first groove;
and/or, the second light adjusting structure is located between the isolation structure and the light blocking structure;
and/or, the second light adjusting structure is located between the light blocking structure and the first light adjusting structure;
and/or, the second light adjusting structure is located on a side of the first light adjusting structure away from the substrate.

11. The display panel according to claim 7, wherein the isolation structure and/or the light blocking structure is a light absorbing material or a light reflecting material.

12. A driving method of a display panel, for driving the display panel according to claim 1, wherein the driving method comprises:
in peep-proof mode, controlling the first light-emitting element to emit light; and
in shared mode, controlling the second light-emitting element to emit light.

13. The driving method of a display panel according to claim 12, further comprising: in the shared mode, controlling the first light-emitting element to emit light while controlling the second light-emitting element to emit light.

14. A display device, comprising the display panel according to claims 1.

15. The display device according to claim 14, wherein the display panel further comprises an isolation structure, the isolation structure is at least partially located on a side of the first light-emitting element and the second light-emitting element away from the substrate; and
on a plane perpendicular to the first direction, the isolation structure is at least partially located between the first light-emitting element and the second light-emitting element, and an orthographic projection of the isolation structure on the substrate does not overlap with an orthographic projection of the first groove on the substrate.

16. The display device according to claim 15, wherein both the first light-emitting element and the second light-emitting element comprise a first electrode, an organic light-emitting layer, and a second electrode sequentially stacked on the substrate, and on the plane perpendicular to the first direction, interfacial regions are formed between the first light-emitting element and the second light-emitting element, the interfacial regions comprise a first interfacial region and a second interfacial region, wherein,
the isolation structure is arranged in the first interfacial region, and separates the first electrode, the organic light-emitting layer, and the second electrode of the first light-emitting element from the first electrode, the organic light-emitting layer, and the second electrode of the second light-emitting element, respectively; and
the isolation structure is not arranged in the first interfacial region, and for the first light-emitting element and the second light-emitting element, conduction between the second electrodes is achieved through the second interfacial region.

17. The display device according to claim 15, wherein a ratio of a height of the isolation structure along the first direction to the depth of the first groove along the first direction is 0.5 to 1.

18. The display device according to claim 15, wherein,
the isolation structure is an integrated structure, a projection area of the orthographic projection of the isolation structure on the substrate gradually increases along the first direction;
or, the isolation structure comprises a first isolation portion and a second isolation portion sequentially stacked on the substrate, an orthographic projection of an end face of the first isolation portion facing the second isolation portion on the substrate is located in an orthographic projection of the second isolation portion on the substrate, and a projection area of the orthographic projection of the end face of the first isolation portion facing the second isolation portion on the substrate is smaller than a projection area of the orthographic projection of the second isolation portion on the substrate.

19. The display device according to claim 15, wherein the display panel further comprises a light blocking structure, located on a side of the isolation structure away from the substrate, wherein an orthographic projection of the light blocking structure on the substrate at least partially overlaps with the orthographic projection of the isolation structure on the substrate, a light exit blind region is formed between the light blocking structure and the isolation structure, and the light exit blind region is located outside an angle range of a first viewing angle.

20. The display device according to claim 19, wherein a height of the isolation structure along the first direction is less than a height of the light blocking structure along the first direction;
and/or, a width of the isolation structure in a direction perpendicular to the first direction is greater than a width of the light blocking structure in the direction perpendicular to the first direction.
